(19) United States
(12) Patent Application Publication
(10) Pub. No.: US 2007/0243662 A1
(43) Pub. Date: Oct. 18, 2007

(54) Packaging of MEMS devices

(76) Inventors: Donald W. Johnson, Wayland, MA (US); Milind P. Nagale, Lowell, MA (US)

Correspondence Address: WIGGIN AND DANA LLP;ATTENTION: PATENT DOCKETING, ONE CENTURY TOWER, P.O. BOX 1832, NEW HAVEN, CT, 06508-1832, US

(21) Appl. No.: 11/716,771

(22) Filed: Mar. 12, 2007

Related U.S. Application Data
(60) Provisional application No. 60/784,071, filed on Mar. 17, 2006.

(51) Int. Cl. H01L 21/00

(52) U.S. Cl. 438/106

(57) ABSTRACT

The present invention is directed to a process for packaging a microelectrical, micromechanical, microelectromechanical (MEMS) or microfluidic component on a substrate by forming cavities made from crosslinked photoresists on an easily removable second substrate, bonding the cavities to third substrates containing selected microdevices, then peeling off the removable second substrate.

### CROSS-REFERENCE TO RELATED APPLICATIONS

This application claims the benefit of U.S. Provisional Application Ser. No. 60/784,071 filed Mar. 17, 2006.

### BACKGROUND OF THE INVENTION

1. Field of the Invention

The present invention relates to packaging of microstructures. In particular, the present invention relates to a packaging process where the package side is manufactured independent of the manufacture of the device component and then the resulting package component is bonded with the resulting device component at the wafer level using a low-temperature bonding process.

2. Brief Description of Art

The use of SU-8 photoresists for making “permanent” structures with high aspect ratios is well known in the Micro Electro Mechanical Systems (MEMS) art. SU-8 is a negative tone, chemically amplified epoxy photoresist system which has been imaged by near UV, x-ray and e-beam irradiation. SU-8 has a number of excellent properties such as its high resolution, high aspect ratio capability, its easy processing, its chemical resistance, its mechanical strength and its applicability to 3-D processing. Due to its simple and low cost fabrication capability, SU-8 has been employed to fabricate numerous MEMS components such as micro-fluidic channels, lab-on-a-chip devices, sensors and actuators, optical devices, passivation layers, dielectric components, and MEMS packages among others.

Curing of SU-8 under recommended processing conditions provides micron scale features with high aspect ratios, high chemical resistance and mechanical toughness. Accordingly, SU-8 has already found widespread application in the manufacture of inkjet cartridges (U.S. Patent Application Publication No. 2004-0196335), micro-spring probe cards and RF MEMS packaging (Daeche, F. et. al., “Low Profile Packaging Solution for RF-MEMS Suitable for Mass Production”, presentation in Proc. 36th International Symposium on Microelectronics, Boston, November 2003.) In addition, a number of references have recently addressed the low temperature bonding of SU-8 for silicon-to-silicon bonding of MEMS devices (U.S. Pat. No. 6,669,803), optical elements (Aguirregabiria, A. et. al., Novel SU-8 Multilayer Technology Based on Successive CMOS Compatible Adhesive Bonding and Kapton Releasing Steps for Multilevel Microfluidic Devices”, embedded micro-fluidic devices (Blanco, F. J. et. al., “Novel Three-Dimensional Embedded SU-8 Microchannels Fabricated Using a Low Temperature Full Wafer Adhesive Bonding”, J. Micromech. Microeng. 14:1047 (2004)), lab-on-a-chip structures, wherein 3-D structures are fabricated using imaged SU-8 bonded to cured or uncured SU-8 or PMMA (Balslev, S. et. al., “Fully Integrated Optical System For Lab-on-a-Chip Applications”, Proc. 17th IEEE International Conference on Micro Electro Mechanical Systems, Maastricht, NL, January 2004; Bilinberg, B. et. al., “PMMA to SU-8 Bonding for Polymer Based Lab-on-a-Chip Systems with Integrated Optics”, submitted to J. Micromech Microeng.) and biochemical reactors (Schultze, J L M et. Al., “Micro SU-8 chamber for PCR and Fluorescent Real-Time Detection of Salmonella spp. DNA, Proc. μTAS 2006 Conferences, Vol 2, 1423 (2006)).

Typically SU-8 films are exposed to form the latent images, then processed at 90-95° C. bake temperatures to crosslink the exposed sections of the film which are then developed to remove the unexposed, uncrosslinked material leaving the desired cross-linked structures attached to a substrate. Unfortunately, it is not possible to bond these structures directly to silicon, glass or metal structures because the SU-8 is too crosslinked to have any adhesive strength. Under cured SU-8 structures do not work either.

The use of low temperature bonding can also be useful in applications where micro-structures are modified with bioactive materials such as enzymes, where the use of high temperatures or longer bonding times can deactivate the biological molecule of interest. Examples of these processes are based on the successive bonding of two lithographically imaged SU-8 layers on separate wafers or the bonding of one imaged SU-8 layer to an uncured SU-8 or PMMA bonding layer, among others. In these cases the wafers are brought into contact, pressed together and then heated sufficiently to cause bonding of the two polymer layers together. In several cases, the two similarly or complementarily imaged layers are prepared on two separate silicon or glass wafers or combinations of both and the two wafers bonded together under pressure and heat. In another case the two lithographic steps are carried out on two different substrates, where one can be silicon, processed silicon or a glass wafer and the other a Kapton thick film coated with SU-8. Here standard lithographic processing and developing steps are used to image the standard bottom substrate before the bonding process. However, the SU-8 layer on the Kapton film has been exposed only and is employed undeveloped during the bonding process. After the bonding of the two SU-8 layers the Kapton film is peeled off and the SU-8 stack developed. By repeating the process on top of this structure, multilayer structures of SU-8 have been obtained.

Imaged SU-8 has further been used to build walls around MEMS structures and then a lid is attached on top, thereby generating a cavity to protect or package the MEMS device (Daeche et al., supra). Again a bonding layer is typically used to gain the requisite adhesive strength between the cover and the walls. As described, liquid SU-8 is spin coated onto the device wafer and imaged to form the walls of the device. While this works well in this case, the coating of a liquid resist over an active MEMS component frequently cannot be tolerated. Secondly, application of the cover is not a trivial process in that liquid SU-8 cannot be coated over the cavity and unnamed processing tricks are necessary to create the cover. Bonding of a separate cover, such as glass, again requires the use of a bonding layer but can be used. Ideally, one would like to be able to build the wall structures on a separate surface thereby avoiding contact of liquid resists and developers with the MEMS components and then bond the wall structures directly to the substrate, and preferably be able to build the cavity, lid and all, and bond the entire cavity to the substrate as depicted in FIG. 1. To date this has not been accomplished to our knowledge because imaged SU-8 is not sufficiently adhesive to bond directly to a hard substrate such as silicon or glass. Further, a dry film version of SU-8 such as described above has not been commercially available to make the process readily usable.

Packaging of microstructures such as flow channels, fluid reservoirs, and particularly sensors and actuators useful for MEMS, microfluidics and RF MEMS applications, is becoming increasingly important, and frequently, packaging costs for MEMS devices may exceed 50% of the total device cost. Achieving a wafer-scale packaging process with simple and inexpensive materials and processes will be required for economical mass production of MEMS components. Furthermore, processes that are compatible with conventional IC wafer processing techniques will be attractive due to the ability to integrate the wafer component and the package component seamlessly. Hence this process can also be applied to IC packaging applications; particularly to wafer level packaging and 3-D interconnect processes. The present invention is believed to address these needs.

### BRIEF SUMMARY OF THE INVENTION

In one aspect, the present invention is directed to a process for packaging a microelectrical, micromechanical, microelectromechanical (MEMS) or microfluidic component on a substrate, comprising the steps of:

(a) forming a first laminate comprising a first negative photoimagable polymeric photoresist layer positioned on a first substrate;

(b) forming a second laminate comprising a second negative photoimagable polymeric photoresist layer positioned on a second substrate;

(c) exposing the first laminate to radiation energy to form a latent imaged portion in the first photoimagable polymeric photoresist layer;

(d) bonding the first laminate to the second laminate so that the imaged portion is brought into contact with the second photoimagable polymeric photoresist layer;

(e) exposing a portion of the combined first and second photoimagable polymeric photoresist layers to radiation energy to form a second latent image in the combined photoresist layer; the combined exposed portions of the first and second photoresist layers corresponding to cover and wall portions, respectively, of at least one packaging structure for the microelectrical, micromechanical, microelectromechanical (MEMS) or microfluidic component;

(f) removing the second substrate from the bonded laminates;

(g) post exposure baking (PEB) the bonded laminates to crosslink the previously exposed areas of the films;

(h) developing the post exposure baked bonded laminates to remove the non-crosslinked portions of the first and second photoresist layers and leaving a resulting first side comprising the cross-linked portions corresponding to the packaging structure positioned on the first substrate;

(i) forming a second side comprising at least one microelectrical, micromechanical, microelectromechanical (MEMS) or microfluidic device on a third substrate;

(j) bonding the resulting first side of step (h) to the second side of step (i) so that each respective packaging structure overlaps each device and forms a bond with the third substrate; and

(k) removing the first substrate from the combined first and second sides.

In another aspect, the present invention is directed to a process for packaging a microelectrical, micromechanical, microelectromechanical (MEMS) or microfluidic component on a substrate, comprising the steps of:

(a) forming a laminate comprising a negative photoimagable polymeric photoresist layer positioned on a substrate;

(b) exposing a portion of the photoimagable polymeric photoresist layer to radiation energy to form a latent image in the photoresist layer; the exposed portions of the photoresist layers corresponding to wall portions of at least one packaging structure for the microelectrical, micromechanical, microelectromechanical (MEMS) or microfluidic component;

(c) removing the substrate from the bonded laminates;

(d) post exposure baking (PEB) the bonded laminates to crosslink the previously exposed areas of the films;

(e) developing the post exposure baked bonded laminates to remove the non-crosslinked portions of the first and second photoresist layers and leaving a resulting first side comprising the cross-linked portions corresponding to the packaging structure positioned on the first substrate;

(f) forming a second side comprising at least one microelectrical, micromechanical, microelectromechanical (MEMS) or microfluidic device on a third substrate;

(g) bonding the resulting first side of step (e) to the second side of step (f) so that each respective packaging structure overlaps each device and forms a bond with the third substrate; and

(h) removing the first substrate from the combined first and second sides.

These and other aspects will become apparent upon reading the following detailed description of the invention.

### BRIEF DESCRIPTION OF THE DRAWINGS

The invention will be more fully understood from the following detailed description taken in conjunction with the accompanying drawings in which:

FIG. 1 is directed to a fabrication scheme for the wafer level imaging and bonding of structures on a polymer film to a substrate populated with at least one microelectrical, micromechanical, microelectromechanical (MEMS) or microfluidic device; and

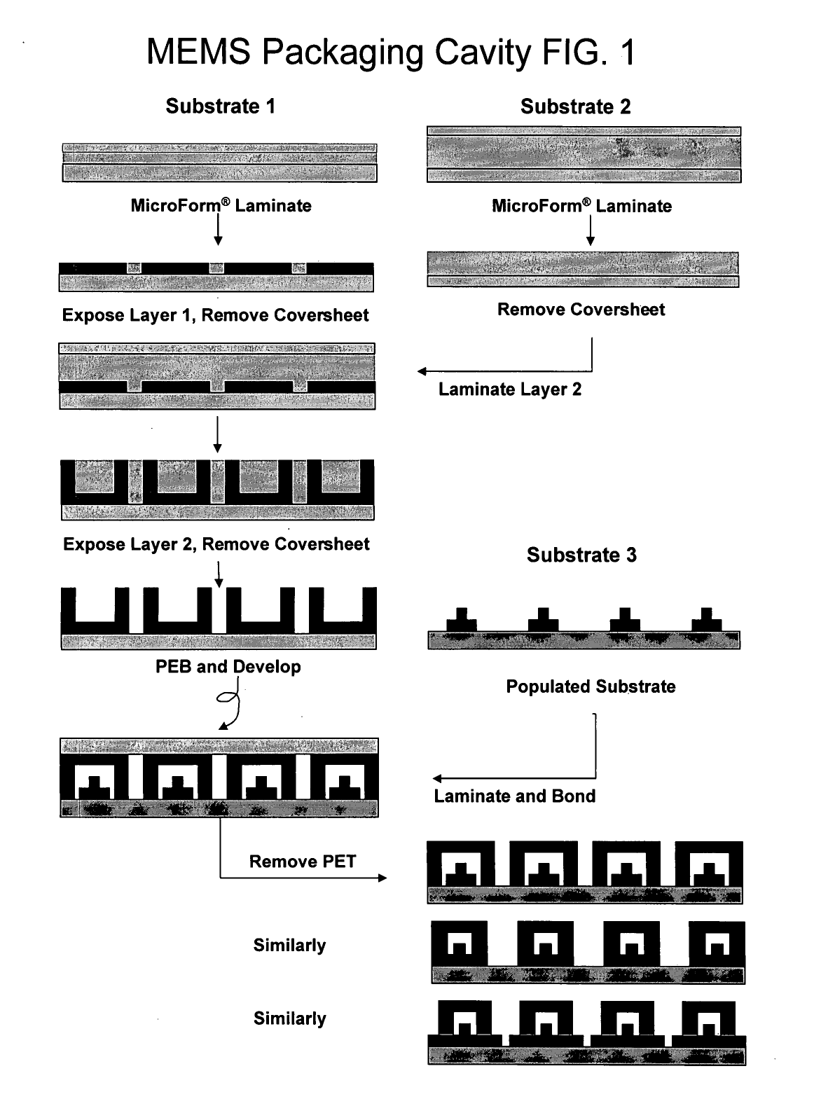

FIG. 2 is directed to a fabrication scheme for the wafer level imaging and bonding of wall structures on a polymer film to a substrate populated with at least one microelectrical, micromechanical, microelectromechanical (MEMS) or microfluidic device, followed by the subsequent bonding of a subsequent substrate.

### DETAILED DESCRIPTION OF THE INVENTION

As indicated above, the present invention is directed to a multistep process for packaging single or multiple microelectrical, micromechanical, microelectromechanical (MEMS) or microfluidic components on a substrate. The process basically involves manufacturing the package side independent of the device components, and then bonding the two sides together at the wafer level using low-temperature bonding methods. The present invention has several advantages, including, (1) avoiding contact of the device components with liquid or dry film photoresists, resist developers or other processing chemicals; (2) achieving bonding of the packaging component to the device component without complex fabrication steps; (3) providing packaging structures that are mechanically rigid and also resistant to a majority of chemical environments; and (4) allowing for easy changes to packaging design and dimensions due to changes in device design and dimensions.

In the art related to photoimagable compositions, photoresists are generally understood to be temporary coatings that are used to selectively protect one area of a substrate from another such that the operation of a subsequent process takes place only in an area of the substrate that is not covered by the photoresist. Once this subsequent operation has been completed, the photoresist is removed. Thus, the properties of such temporary photoresists need only be those required to obtain the required image profile and be resistant to the action of the subsequent process steps. However, the present invention also addresses applications wherein the photoresist layer is not removed and is used as a permanent structural component of the device being fabricated. In the case of use of the photoresist as a permanent layer, the material properties of the photoresist film must be compatible with the intended function and end use of the device. Therefore, photoimagable layers that remain as a permanent part of the device are termed herein as permanent photoresists.

New versions of SU-8 have been recently introduced which are more flexible, tougher and give uncured films with lower Tg's than the standard SU-8 and SU-8 2000 resists, U.S. Patent Application Publication No. 2005/0260522 A1. By using these new resists it is possible to develop methods which allow one to generate SU-8 images that can be readily developed to give fine line structures and still provide excellent adhesion at low bonding temperatures to a wide range of typical substrates such as silicon wafers, glass, metals and polymers as well as SU-8. Further, research samples of the dry film version of this resist have become available and provide a very unique opportunity to readily make such structures and at the same time allow multilayer potential for stacked devices, micro-fluidic structures and optical devices as well as a simple packaging process for a multitude of MEMS devices. In addition, the dry film material is even more convenient to use because it dramatically increases throughput since it is no longer necessary to bake for extended periods of time, while at the same time providing uniform surfaces with no edge bead. Dry film is also useful for applications with irregularly shaped substrates and the deposition of multiple layers can be achieved with a simple process of hot roll lamination or wafer bonding.

The ability to process SU-8 pre-coated on transparent polyethylene terephthalate (PET), polyethylene naphthalate (PEN) or polyimide (Kapton) films allows for alignment to subsequent layers during patterning, as well as for alignment to the populated substrate. The SU-8 process allows one to achieve bonding without complex fabrication approaches. In addition, the process provides structures that are mechanically rigid and also resistant to variety of chemical environments.

The photoimagable materials used in the method of the present invention must fulfill two general criteria. First, the photoimagable materials must be capable of bonding to a substrate after exposure, post develop bake and developing. Second, the photoimagable material must be crosslinkable to a level that allows development of the wall structures as small as 10 μm in width and aspect ratios greater than 1:1, but still maintain the capability to be subsequently bonded to a third substrate. Several new photoimagable materials currently meet these criteria.

SU-8 3000, SU-8 4000, MicroForm® 3000 and MicroForm® 4000

Preferred first and second negative photo polymerizable polymeric photoresist used in this invention are photoresist compositions disclosed in U.S. Patent Application Publication No. 2005/0260522 A1, herein incorporated by reference in its entirety. These photoresist materials are available commercially under the tradename SU-8 3000 and SU-8 4000 and are available from MicroChem. Corp., Newton, Mass. MicroForm 3000 and MicroForm 4000 are dry film versions of SU-8 3000 and SU-8 4000 respectively as disclosed in said Application and are also noted in U.S. patent application Ser. No. 60/680,801, 13 May 2005, herein incorporated by reference in its entirety. Briefly, the photoresists disclosed in these publications are useful for making negative-tone, permanent photoresist layers and comprise:

(A) one or more bisphenol A-novolac epoxy resins according to Formula I

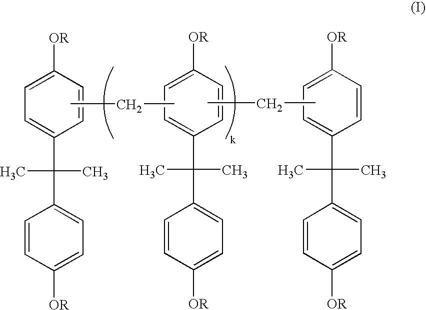

wherein each group R may be individually selected from glycidyl or hydrogen and k in Formula I is a real number ranging from 0 to about 30;

(B) one or more epoxy resins selected from the group represented by Formulas BIIa and BIIb;

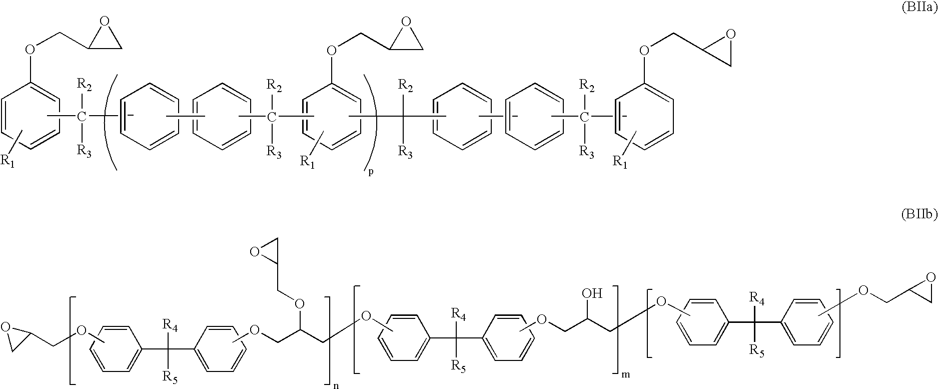

wherein each R₁, R₂ and R₃ in Formula BIIa are independently selected from the group consisting of hydrogen or alkyl groups having 1 to 4 carbon atoms and the value of p in Formula BIIa is a real number ranging from 1 to 30; the values of n and m in Formula BIIb are independently real numbers ranging from 1 to 30, and R₄ and R₅ in Formula BIIb are independently selected for the group consisting of hydrogen, alkyl groups having 1 to 4 carbon atoms, or trifluoromethyl;

(C) one or more cationic photoinitiators (also known as photoacid generators or PAGs); and

(D) one or more solvents in the liquid formulations.

In addition to components (A) through (D) inclusively, the composition according to the invention can optionally comprise one or more of the following additive materials: (E) one or more optional epoxy resins; (F) one or more reactive monomers; (G) one or more photosensitizers; (H) one or more adhesion promoters: (J) one or more light absorbing compounds including dyes and pigments; and (K) one or more organoaluminum ion-gettering agents. In addition to components (A) through (K) inclusively, the composition according to the invention can also optionally comprise additional materials including, without limitation, flow control agents, thermoplastic and thermosetting organic polymers and resins, inorganic filler materials, radical photoinitiators, and surfactants.

The permanent photoresist composition is comprised of: a bisphenol A novolac epoxy resin (A); one or more epoxy resins (B) represented by general Formulas BIIa and BIIb; one or more cationic photoinitiators (C); as well as optional additives.

Bisphenol A novolac epoxy resin (A) suitable for use in the present invention have a weight average molecular weight ranging from 2000 to 11000 are preferred and resins with a weight average molecular weight ranging from 4000 to 7000 are particularly preferred. Epicoat® 157 (epoxide equivalent weight of 180 to 250 grams resin per equivalent of epoxide (g resin/eq or g/eq) and a softening point of 80-90° C.) made by Japan Epoxy Resin Co., Ltd. Tokyo, Japan, and EPON® SU-8 Resin (epoxide equivalent weight of 195 to 230 g/eq and a softening point of 80 to 90° C.) made by Hexion Specialty Chemicals, Inc., Houston, Tex. and the like are cited as preferred examples of bisphenol A novolac epoxy resins suitable for use in the present invention.

Epoxy resins (B) according to Formulas (BIIa) and (BIIb) are flexible and strong and are capable of giving these same properties to the pattern that is formed. An example of the epoxy resin (BIIa) used in the present invention are the epoxy resins according to Japanese Kokai Patent No. Hei 9 (1997)-169,834 that can be obtained by reacting di(methoxymethylphenyl) and phenol and then reacting epichlorohydrin with the resin that is obtained. An example of a commercial epoxy resin according to Formula IIa is epoxy resin NC-3000 (epoxide equivalent weight of 270 to 300 g/eq and a softening point of 55 to 75° C.) made by Nippon Kayaku Co., Ltd. Tokyo, Japan, and the like are cited as examples. It is to be understood that more than one epoxy resin according to Formula BIIa can be used in the compositions according to the invention. Specific examples of epoxy resins BIIb that may be used in the invention are NER-7604, NER-7403, NER-1302, and NER 7516 resins manufactured by Nippon-Kayaku Co., Ltd, Tokyo, Japan. It is to be understood that more than one epoxy resin according to Formula BIIb can be used in the compositions according to the invention.

Compounds that generate a protic acid when irradiated by active rays, such as ultraviolet rays, and the like, are preferred as the cationic photopolymerization initiator (C) used in the present invention. Aromatic iodonium complex salts and aromatic sulfonium complex salts are cited as examples. Di-phenyliodonium hexafluorophosphate, diphenyliodonium hexafluoroantimonate, di(4-nonylphenyl)iodonium hexafluorophosphate, [4-(octyloxy)phenyl]phenyliodonium hexafluoroantimonate, di-(4-t-butylphenyl)iodonium tris-(trifluoromethylsulfonium)methide and the like are cited as specific examples of the aromatic iodonium complex salts that can be used. Moreover, triphenylsulfonium hexafluorophosphate, triphenylsulfonium hexafluoroantimonate, triphenylsulfonium tetrakis(pentafluorophenyl)borate, 4,4′-bis[diphenylsulfonium]diphenylsulfide bis-hexafluorophosphate, phenylcarbonyl-4′-diphenylsulfonium diphenylsulfide hexafluorophosphate, phenylcarbonyl-4′-diphenylsulfonium diphenylsulfide hexafluoroantimonate, diphenyl [4-(phenylthio)phenyl]sulfonium hexafluoroantimonate, diphenyl-[4-(phenylthio)phenyl]sulfonium tris-(perfluoroethyl)trifluorophosphate and the like can be cited as specific examples of the aromatic sulfonium complex salt that can be used. Certain ferrocene compounds, such as Irgacure 261 manufacture by Ciba Specialty Chemicals may also be used. The cationic photoinitiators (C) can be used alone or as mixtures of two or more compounds.

The referenced solvent (D) is no longer present in the laminate films.

Optionally, it may be beneficial to use an additional epoxy resin (E) in the composition. Depending on its chemical structure, optional epoxy resin (E) may be used to adjust the lithographic contrast of the photoresist or to modify the optical absorbance or the physical properties of the photoresist film. The optional epoxy resin (E) may have an epoxide equivalent weight ranging from 150 to 250 grams resin per equivalent of epoxide. Examples of optional epoxy resins suitable for use include EOCN 4400, an epoxy cresol-novolac resin with an epoxide equivalent weight of about 195 g/eq manufactured by Nippon Kayaku Co., Ltd., Tokyo, Japan. Another preferred commercial example is EHPE 3150 epoxy resin which has an epoxide equivalent weight of 170 to 190 g/eq and is manufactured by Daicel Chemical Industries, Ltd., Osaka, Japan.

Optionally, it may be beneficial in certain embodiments to use a reactive monomer compound (F) in the compositions according to the invention. Inclusion of reactive monomers in the composition helps to increase the flexibility of the uncured and cured film. Glycidyl ethers containing two or more glycidyl ether groups are examples of reactive monomer (F) that can be used. The glycidyl ethers can be used alone or as mixtures of two or more. Trimethylolpropane triglycidyl ether and polypropylene glycol diglycidyl ether are preferred examples of reactive monomers (F) that can be used in the invention. Alicyclic epoxy compounds can also be used as reactive monomer (F) in this invention and 3,4-epoxycyclohexylmethyl methacrylate and 3,4-epoxycyclohexylmethyl-3′,4′-epoxycyclohexane carboxylate may be cited as examples.

Optionally, photosensitizer compounds (G) may be included in the composition so that more ultraviolet rays are absorbed and the energy that has been absorbed is transferred to the cationic photopolymerization initiator. Consequently, the process time for exposure is decreased. Anthracene and N-alkyl carbazole compounds are examples of photosensitizers that can be used in the invention. Anthracene compounds with alkoxy groups at positions 9 and 10 (9,10-dialkoxyanthracenes) are preferred photosensitizers (G). The 9,10-dialkoxyanthracenes can also have substituent groups. C1 to C4 alkyls, such as methyl, ethyl, propyl and butyl are given as examples of the alkyl moiety on the anthracene ring. The sensitizer compounds (G) can be used alone or in mixtures of two or more.

Examples of optional adhesion promoting compounds (H) that can be used in the invention include: 3-glycidoxypropyltrimethoxysilane, 3-glycidoxypropyltriethoxysilane, 3-mercaptopropyltrimethoxysilane, vinyltrimethoxysilane, [3-(methacryloyloxy)propyl]tri-methoxysilane, and the like.

Optionally, it may be useful to include compounds (J) that absorb actinic rays and have an absorbance coefficient at 365 nm of 15 L/g.cm or higher. Such compounds can be used to provide a relief image cross section that has a reverse tapered shape such that the imaged material at the top of the image is wider than the imaged material at the bottom of the image. Specific examples of the compounds (J) that can be used in the present invention either singly or as mixtures.

Optionally, an organic aluminum compound (K) can be used in the present invention as an ion-gettering agent. There are no special restrictions on the organic aluminum compound as long as it is a compound that has the effect of adsorbing the ionic materials remaining in the cured product. These components (K) can be used alone or as a combination of two or more components and they are used when it is necessary to alleviate detrimental effects of ions derived from the above-mentioned photoacid generator compounds (C).

The amount of bis-phenol novolac component A that may be used is 5-90 weight % of the total weight of components A, B, and C and where present, optional epoxy resin E, reactive monomer F, and adhesion promoter H, and more preferably 25-90 weight % and most preferably 40-80%.

The amount of epoxy resin component B that may be used is 10-95 weight % of the total weight of components A, B, and C and where present, optional epoxy resin E, reactive monomer F, and adhesion promoter H, and more preferably 15-75 weight % and most preferably 20 to 60 weight %.

The amount of photoacid generator compound C that may be used is 0.1 to 10 weight % of the total weight of epoxy resin components A and B, and where present, optional epoxy resin E, reactive monomer F, and adhesion promoter H. It is more preferred to use 1-8 weight % of C and it is most preferred to use 2-6 weight %.

When an optional epoxy resin E is used, the amount of resin E that may be used is 5-40 weight % of the total weight of components A, B, and C and where present, optional epoxy resin E, reactive monomer F, and adhesion promoter H and more preferably 10-30 weight % and most preferably 15-30 weight %.

When an optional reactive monomer F is used, the amount of F that may be used is 1-20 weight % of the total weight of components A, B, and C and where present, optional epoxy resin E, reactive monomer F, and adhesion promoter H and more preferably 2-15 weight % and most preferably 4-10 weight %.

When used, optional photosensitizer component G may be present in an amount that is 0.05 to 4.0 weight % relative to the photoinitiator component C and it is more preferred to use 0.5-3.0 weight % and most preferred to use 1-2.5 weight %.

Optionally, epoxy resins, epoxy acrylate and methacrylate resins, and acrylate and methacrylate homopolymers and copolymers other than components A, B, and E can be used in the present invention. Phenol-novolac epoxy resins, trisphenolmethane epoxy resins, and the like are cited as examples of such alternate epoxy resins, and a methacrylate monomer such as pentaerythritol tetra-methacrylate and dipentaerythritol penta- and hexa-methacrylate, a methacrylate oligomer such as epoxymethacrylate, urethanemethacrylate, polyester polymethacrylate, and the like are cited as examples of methacrylate compounds. The amount used is preferably 0 to 50 weight % of the total weight of components A and B and E.

In addition, optional inorganic fillers such as barium sulfate, barium titanate, silicon oxide, amorphous silica, talc, clay, magnesium carbonate, calcium carbonate, aluminum oxide, aluminum hydroxide, montmorillonite clays, and mica powder and various metal powders such as silver, aluminum, gold, iron, CuBiSr alloys, and the like can be used in the present invention. The content of inorganic filler may be 0.1 to 80 weight % of the composition. Likewise, organic fillers such as polymethylmethacrylate, rubber, fluoropolymers, crosslinked epoxies, polyurethane powders and the like can be similarly incorporated.

When necessary, various materials such as crosslinking agents, thermoplastic resins, coloring agents, thickeners, and agents that promote or improve adhesion can be further used in the present invention. When these additives and the like are used, their general content in the composition of the present invention is 0.05 to 10 weight % each, but this can be increased or decreased as needed in accordance with the application objective.

XP SU-8 Flex and XP MicroForm® 1000

Another preferred photopolymerizable polymeric photoresist useful for the first and second photoresists according to the method of the present invention are photoresist compositions disclosed in U.S. Pat. No. 6,716,568 B2 and U.S. Patent Application Publication No. 2005/0266335 A1, herein incorporated by reference in their entirety. These photoresist materials are available commercially under the tradenames XP SU-8 Flex and MicroForm® 1000 and are available from MicroChem. Corp., Newton, Mass. MicroForm 1000 is a dry film form of the SU-8 Flex composition. Briefly, the photoresist compositions disclosed in these publications are photoresists made from (A) at least one epoxidized polyfunctional bisphenol A formaldehyde resin; (B) at least one polycaprolactone polyol reactive diluent; (C) at least one photoacid generator, and (D) at least one solvent to dissolve (A), (B) and (C). A similar composition is disclosed in Kieninger, J. et. al., “3D Polymer Microstructures by Laminating Films”, Proceedings of μTAS 2004 Vol. 2, Malmö, SE, p363 (2004).

The epoxidized polyfunctional bisphenol A resin (A) suitable for use in this photoresist has a weight average molecular weight ranging from 2000 to about 11000 are preferred and resins with a weight average molecular weight ranging from 3000 to 7000 are particularly preferred. Epicoat® 157 (epoxide equivalent weight of 180 to 250 and a softening point of 80-90° C.) made by Japan Epoxy Resin Co., Ltd., and EPON® SU-8 Resin (an epoxidized polyfunctional bisphenol A formaldehyde novolak resin having an average of about eight epoxy groups and having an average molecular weight of about 3000 to 6000 and having epoxide equivalent weight of 195 to 230 g/eq and a softening point of 80 to 90° C.) made by Hexion Specialty Chemicals, Inc. and the like are cited as preferred examples of the epoxidized polyfunctional bisphenol A novolac resins suitable for use in the present invention. A preferred structure is shown in Formula I above wherein R is hydrogen or glycidyl and k is a real number ranging from 0 to about 30.1

The polycaprolactone polyol component (B) contains hydroxy groups capable of reacting with epoxy groups under the influence of a strong acid catalyst and serves as reactive diluent for the epoxy resin. The polycaprolactone polyols soften the dried coatings and thereby prevent the coating from cracking when coated flexible substrates are wound around cylinders to provide rolls of dry film photoresist. This flexibility feature is essential for practical operation of the invention because the laminating machinery commonly used to apply dry film photoresists requires that a roll of dry film resist be mounted on the laminating machine. Examples of polycaprolactone polyols suitable for use in the invention are “TONE 201” and “TONE 305” obtained from Dow Chemical Company. “TONE 201” is a difunctional polycaprolactone polyol with a number average molecular weight of about 530 gram/mole, with the structure shown as Formula 2,

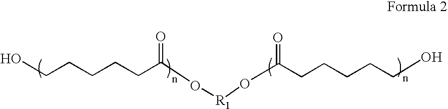

where R₁ is a proprietary aliphatic hydrocarbon group, and with average n=2. TONE 305 is a trifunctional polycaprolactone polyol with a number average molecular weight of about 540 gram/mole, with the structure shown as Formula 3,

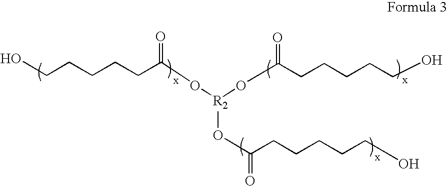

where R₂ is a proprietary aliphatic hydrocarbon group and with average x=1.

Compounds that generate a protic acid when irradiated by active rays, such as ultraviolet rays, and the like, are preferred as the photoacid generator (C) used in this photoresist. Aromatic iodonium complex salts and aromatic sulfonium complex salts are cited as examples. Diphenyliodonium hexafluorophosphate, diphenyliodonium hexafluoroantimonate, di(4-nonylphenyl)iodonium hexafluorophosphate, [4-(octyloxy)phenyl]phenyliodonium hexafluoroantimonate, di-(4-t-butylphenyl)iodonium tris-(trifluoromethylsulfonium)methide and the like are cited as specific examples of the aromatic iodonium complex salts that can be used. Moreover, triphenylsulfonium hexafluorophosphate, triphenylsulfonium hexafluoroantimonate, triphenylsulfonium tetrakis(pentafluorophenyl)borate, 4,4′-bis[diphenylsulfonium]diphenylsulfide bis-hexafluorophosphate, phenylcarbonyl-4′-diphenylsulfonium diphenylsulfide hexafluorophosphate, phenylcarbonyl-4′-diphenylsulfonium diphenylsulfide hexafluoroantimonate, diphenyl [4-(phenylthio)phenyl]sulfonium hexafluoroantimonate, diphenyl-[4-(phenylthio)phenyl]sulfonium tris-(perfluoroethyl)trifluorophosphate and the like can be cited as specific examples of the aromatic sulfonium complex salt that can be used. Certain ferrocene compounds, such as Irgacure 261 manufacture by Ciba Specialty Chemicals may also be used. The cationic photoinitiators (C) can be used alone or as mixtures of two or more compounds.

The preferred photoacid generator consists of a mixture of triaryl sulfonium salts with structure shown below as Formula 4,

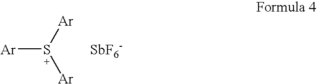

where Ar represents a mixture of aryl groups. Such a material is commercially available from Dow Chemical Company under the trade name CYRACURE Cationic Photoinitiator UVI-6976, which consists of an approximately 50% solution of compound of Formula 4 dissolved in propylene carbonate. Also useful are single component versions of Formula 4, commercially available from San Apro Limited, Kyoto, Japan sold under the trade names CPI-101A or CPI-110A.

The referenced solvent (D) in the compositions are no longer present in the laminate film.

In addition to components (A) through (D) inclusively, the compositions may optionally comprise one or more of the following additive materials: (E) one or more epoxy resins; (F) one or more reactive monomers; (G) one or more photosensitizers; (H) one or more adhesion promoters: (J) one or more light absorbing compounds including dyes and pigments; (K) one or more surface leveling agents, and (L) one or more solvents with a boiling point greater than 150° C. In addition to components (A) through (L) inclusively, the compositions may optionally comprise additional materials including, without limitation, flow control agents, thermoplastic and thermosetting organic polymers and resins, inorganic filler materials, and radical photo initiators.

Implementing the Method of the Invention

In accordance with the method of the invention, a multi-step process is utilized to generate photoimaged polymeric structures of virtually any shape, size, height or position on the micron or millimeter scale on a flexible substrate of limited adhesion which are then bonded to a substrate populated with active devices to encapsulate or form an enclosure around and optionally over such active devices. Such devices include, but are not limited to microelectrical, micromechanical, microelectromechanical (MEMS), or microfluidic devices or components.

The basic steps of the method are as follows:

(a) forming a first laminate comprising a first negative photoimagable polymeric photoresist layer positioned on a first substrate;

(b) forming a second laminate comprising a second negative photoimagable polymeric photoresist layer positioned on a second substrate;

(c) exposing the first laminate to radiation energy to form a latent imaged portion in the first photoimagable polymeric photoresist layer;

(d) bonding the first laminate to the second laminate so that the imaged portion is brought into contact with the second photoimagable polymeric photoresist layer;

(e) exposing a portion of the combined first and second photoimagable polymeric photoresist layer to radiation energy to form a second latent image in the combined photoresist layers; the combined exposed portions of the first and second photoresist layers corresponding to cover and wall portions, respectively, of at least one packaging structure for the microelectrical, micromechanical, microelectromechanical (MEMS) or microfluidic component;

(f) removing the second substrate from the bonded laminates;

(g) post exposure baking (PEB) the bonded laminates to crosslink the previously exposed areas of the films;

(h) developing the post exposure baked bonded laminates to remove the non-crosslinked portions of the first and second photoresist layers and leaving a resulting first side comprising the cross-linked portions corresponding to the packaging structure positioned on the first substrate;

(i) forming a second side comprising at least one microelectrical, micromechanical, microelectromechanical (MEMS) or microfluidic device on a third substrate;

(j) bonding the resulting first side of step (h) to the second side of step (i) so that each respective packaging structure overlaps each device and forms a bond with the third substrate; and

(k) removing the first substrate from the combined first and second sides.

The polymeric structure is typically in the shape of a cavity with the cover or top in contact with the substrate film and the wall or walls on top of the cover. The cover may be a solid piece or it may contain openings to allow access to the outside environment or other features of the populated substrate. The polymeric structure may also contain only the wall or walls in contact with the substrate film. The film containing the polymeric structures is then placed in contact with the populated substrate with the top of the walls in contact with the substrate surface. The walls are then bonded to the substrate under appropriate pressure, temperature and time conditions to effect the permanent bonding of the two surfaces in contact. The bond strength is of such a magnitude so as to allow the enclosed structures to remain protected after typical lifetime testing for such devices. The process is not intended to provide hermetic protection as the polymer is normally not moisture or gas impermeable, but such protection can be readily achieved by coating other protective films over the bonded structures to provide protection to near hermetic levels.

Substrate materials containing such active devices that can be used include, but are not limited to, silicon, silicon dioxide, silicon nitride, silica, quartz, glass, alumina, glass-ceramics, gallium arsenide, indium phosphide, copper, aluminum, nickel, iron, nickel-iron, steel, copper-silicon alloys, indium-tin oxide coated glass, organic films such as polyimide and polyester, any substrate bearing patterned areas of metal, semiconductor, and insulating materials, and the like. Optionally, a bake step may be performed on the substrate to remove absorbed moisture prior to applying the photoresist film in order to improve bond strength. Also for the same purposes a plasma descum, a primer treatment or surface activation step may be employed to clean or activate the surface of the substrate prior to bonding.

The substrate can be populated with virtually any type of device and can include passive devices or structures as well as active devices, whether microelectronical, micromechanical, optoelectronical or microelectromechanical. The actual function or purpose of the device is irrelevant to the purpose of the process. However, the process is primarily designed for the packaging of MEMS devices.

The flexible substrate of limited adhesion on which the polymeric structures are formed is typically polyethylene terephthalate (PET), polyethylene naphthalate (PEN) or polyimide such as Kapton®, although other similar flexible substrates may be used. These films are unique in that they offer a stable support for the photoresist film and also show only limited adhesion to both the cured and uncured photoresist film, Further they have sufficient adhesion to the crosslinked or partially crosslinked polymeric structures as well adequate structural, chemical and thermal stability to allow standard photoresist processing to form such structures without the structures falling off the film during the processing. Yet the adhesion is weak enough so that the film can be easily removed from the polymeric structures once they are bonded to the populated substrate. Further, these flexible films are frequently used as carrier substrates for commercially available dry film photoresist laminates.

The photoimagable laminate materials required for this process can be purchased from commercial sources, where appropriate, or they can be prepared from liquid photoresist compositions by spin coating directly on the flexible films then baking using standard photoresist processes to form the laminate coating on the flexible support film.

The first step of the process is to form the first layer of the polymeric structure on the laminate coating. Typically this is the cover or top of the package structure, which may or may not contain any openings or holes. For convenience the laminate is typically cut or stamped into a circular or wafer shaped piece, although irregular shapes work as well. The film is then exposed in a standard projection, proximity or contact exposure tool with the desired pattern. For ease of handling, the films may be tacked to a more rigid substrate such as a silicon wafer using a temporary adhesive or it may be attached to a dicing tape to provide increased structural rigidity. The laminate can be exposed with the coversheet in place or the coversheet can be removed to provide improved lithographic performance. At this point the latent image of the first layer is embedded in the film and after removal of the cover sheet the second layer can now be attached. However, after exposure and removal of the coversheet, the laminate may also be further processed using the manufacturer's recommended process for the resist to provide the imaged cover structures on the substrate film. This alternative has the advantage of providing alignment structures in the resist to allow alignment of the second or wall layer to the cover layer.

Second, a second layer of resist film is laminated on top of the first layer, whether imaged or not. The second film can be cut or stamped into the desired shape either before or after lamination. A second mask containing typically the wall structures is then aligned to the first imaged layer and exposed as above. Alternatively, the second layer may be imaged without lamination to the first layer, resulting in a structure containing walls only. If these are to be the layer to be bonded to the populated substrate, the coversheet is removed and the processing continued. If additional layers are to be employed this step can be repeated by laminating additional layers until the desired number of layers have been added. The combined laminate layers are then post exposure baked to provide the necessary degree of partial crosslinking to provide the desired structural wall quality and also the requisite “tackiness” to allow the imaged structure to be adequately bonded to the populated substrate.

Achieving partial cross-linking via milder exposure and/or PEB conditions is required for a successful bonding process. Lower exposure energies do not appear to significantly affect the bonding capability of the developed SU-8 structures but do impact the lithographic capability of the process. In most cases it has been found that standard exposure doses are generally preferred. Lower PEB temperatures and times, however, were found to be required in order to obtain an acceptable bonding process with the patterned SU-8 3000, SU-8 4000 or MicroForm structures. This was demonstrated by processing SU-8 3000 films under “standard” conditions, using the typical PEB conditions of 95° C. for 4 minutes, and bonding to a silicon wafer using the same bonding conditions described below. After bonding such structures PEB'd under these conditions, adhesion was found to be unacceptable during the tape test (almost 100% loss).

Choosing an appropriate temperature for PEB requires balancing improved adhesion with a loss in lithographic quality. In this case, we artificially set the target as being able to get better than 2:1 aspect ratios, or 10 μm resist walls in 25 μm thick films or 20 μm resist walls in 50 μm thick films. PEB temperatures of 60, 50, and 40° C. for 2 and 1 minutes were found to be appropriate for processing in this case. Acceptable conditions obtained for 50 μm films were PEB at 60° C. for 2 minutes, followed by a 6 minute development with mild agitation. Sufficient rinsing of the residual developer after the development is complete is necessary because the residual developer contains dissolved photoresist components that will form deposits in the relief image if the residual resist is allowed to dry onto the substrate.

Third, the imaged structures are aligned and bonded to the populated substrate. The bonding can be accomplished on either wafer bonding systems or dry film lamination systems fitted with alignment capabilities. The processing conditions of the films prior to bonding were found to have a bigger impact on adhesion after bonding than the bonding conditions themselves. When properly exposed and PEB'd a wide range of bonding conditions was found to be acceptable. The conditions of 45 psi at 100° C. were chosen as the starting point based on literature reports. Bonding studies showed that a pressure of 45 psi at 95° C. worked well for reasonable adhesion to silicon wafers even under the short bonding times which are obtainable when using a laminator. Higher pressures were not anticipated to be necessary and were not evaluated. Bonding temperatures in excess of 100° C. were also of no benefit. The fact that no more than 100° C. was needed for the bonding is fortuitous in that it allows the use of commercial PET based films rather than the more expensive polyimide which must also be liquid coated.

Bonding studies also showed that such high temperatures and pressure are not necessary. Adequate bonding can be obtained on both wafer bonding and laminating equipment at temperatures as low as 60° C. and pressures as low as 5 psi with various cycle times or lamination speeds. On wafer bonding equipment the lower temperatures provide significantly reduced cycle times due to the relatively slow cooling cycles on these tools. On lamination equipment, lower bonding temperatures and pressures require slower laminating speeds to be effective. A combination of higher temperatures and higher lamination speeds was also successful. Successful bonding of patterned SU-8 4000 or MicroForm 4000 structures to silicon was obtained using only simple hot roll lamination.

Fourth, after lamination of the polymer structures to the populated substrate the film-substrate stack was allowed to cool to room temperature for a few minutes. The carrier film along with any structural support such as dicing tape was readily and cleanly peeled off of the populated substrate, which now contains the polymeric cavities or other structures bonded to the substrate. In some instances the carrier film self-peels from the polymeric structures upon cooling.

Finally, the packaged substrate is hardbaked at 95 to 250° C. for 5 to 30 minutes to improve the bond strength between the polymeric walls and the substrate surface. In fact, all samples which were firmly attached to the substrate after bonding would pass a tape adhesion test after hardbaking to 250° C. for 5 minutes. Many samples would not pass the tape test after a 95° C., 5 min hardbake, but a majority would pass the test after a subsequent 150° C., 30 minute hardbake and all passed after an additional 5 minutes at 250° C.

In an alternative embodiment, the first laminate at step (c) may be post exposure baked and developed prior to bonding the second laminate in step (d). As will be appreciated, the combined first and second sides can be further laminated to a third or subsequent laminate, making a multilayer combined laminate

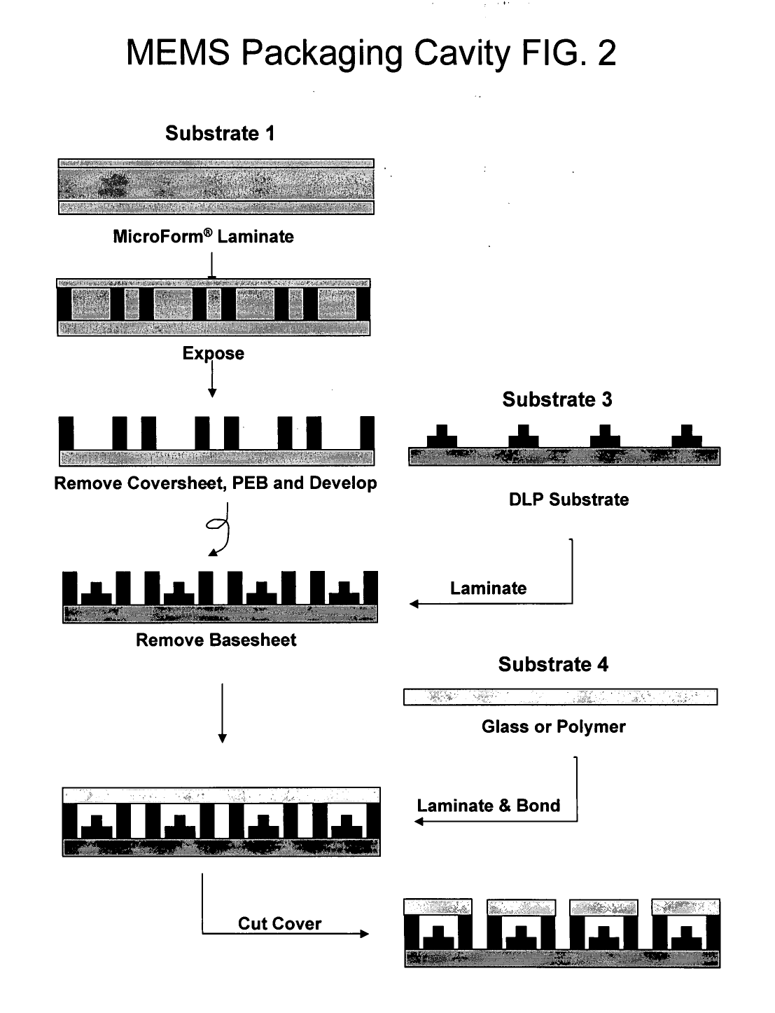

In another alternative embodiment, the first laminate can be omitted and the second layer individually exposed in step (e) to form the second latent image corresponding to the wall layer only. After removal of the second side, the unbonded side of the second layer bonded to the third substrate may also be subsequently bonded to a fourth substrate, such as a second silicon wafer, glass or a polymer sheet. In addition, the walls on the third substrate may be subsequently bonded to a fourth substrate such as another wafer to form a wafer stack, glass or clear plastic to form a transparent cover, or another imaged sheet to form a multiplayer structure, among other possibilities, as shown in FIG. 2. In FIG. 2, as an alternative embodiment, substrates 3 and 4 can be used interchangeably and do not need to be used only in the sequence shown. The steps of this alternative embodiment are as follows:

(a) forming a laminate comprising a negative photoimagable polymeric photoresist layer positioned on a substrate;

(b) exposing a portion of the photoimagable polymeric photoresist layer to radiation energy to form a latent image in the photoresist layer; the exposed portions of the photoresist layers corresponding to wall portions of at least one packaging structure for the microelectrical, micromechanical, microelectromechanical (MEMS), or microfluidic component;

(c) removing the substrate from the bonded laminates;

(d) post exposure baking (PEB) the bonded laminates to crosslink the previously exposed areas of the films;

(e) developing the post exposure baked bonded laminates to remove the non-crosslinked portions of the first and second photoresist layers and leaving a resulting first side comprising the cross-linked portions corresponding to the packaging structure positioned on the first substrate;

(f) forming a second side comprising at least one microelectrical, micromechanical, microelectromechanical (MEMS), or microfluidic device on a third substrate;

(g) bonding the resulting first side of step (e) to the second side of step (f) so that each respective packaging structure overlaps each device and forms a bond with the third substrate; and

(h) removing the first substrate from the combined first and second sides.

Uses

The process of the present invention is generally applicable in the manufacture of enclosed micromechanical, microelectrical, or microelectromechanical (MEMS) components. In this process the active structures of the device are covered with a polymeric cavity which is strongly bonded to the device substrate and protects the active sites from the outside environment. In the process the active device is never brought into contact with potentially damaging liquids, chemicals, or other process materials. For further protection from the environment, the polymeric cavity can be further coated with other polymeric materials, glasses, ceramics or metal films which can act as moisture diffusion barriers, gas diffusion barriers, or provide improved hermeticity. This is a potentially low cost, wafer level packaging approach using a photoimagable resist which remains as a permanent protection over the active portions of the device. The method of the invention may be applied to make a variety of structures, but primarily cavities, caps, walls or channels covering active areas of a device structure.

The process has been primarily designed for the packaging of various MEMS devices which can be of almost any size or height in the micron or millimeter range. It is also highly versatile in that the design can be readily changed to accommodate different designs or changes in the size or shape of the components to be protected. One of the most widely used current application of SU-8 is for RF MEMS packaging and this process is readily applied to this application as well as to other similar applications. Other typical MEMS devices for which it may be applicable are accelerometers, micromirrors, sensors or actuators containing cantilevers or other moving parts, pressure sensors, fluidic channels, biochemical reactors, chemical detectors, electronic noses, blood gas or pressure monitors, or implantable devices.

While the primary target application is MEMS packaging, this process can also be used for a wide number of micromechanical, microelectronic and optoelectronic applications in a similar manner for the protection or encapsulation of such devices. Particularly useful would be wafer level packaging applications including 3-D interconnects and chip stacking. Here the resulting polymeric cavity can provide both the protection of the lower level devices, the spacing between the layers and the bonding platform for the second and subsequent layers.

It can also be used as a low cost method to bond polymer components to a second substrate to prepare, for example, integrated biological separation or detection diagnostic devices. Many MEMS devices are, in fact, hybrid devices where different MEMS functionalities are brought together on a single device. The ability to bond already formed polymeric MEMS structures directly to a separation or diagnostic device, for example, without having to coat and process the polymeric component on the device may offer significant advantage in cost or manufacturing efficiency. Similarly a glass or metal component, for instance, may be bonded to a polymeric device to again generate such a hybrid MEMS structure.

The present invention is further described in detail by means of the following Experiments and Comparisons. All parts and percentages are by weight and all temperatures are degrees Celsius unless explicitly stated otherwise.

### EXAMPLES

Initially 25 or 50 μm thick coatings of SU-8 3000 were prepared on polyethylene terephthalate (PET) films by spin coating and baking the liquid resists using standard process conditions. Subsequently, research samples of 25, 50 or 100 μm thick XP MicroForm® 3000 and XP MicroForm® 4000 were used. Exposure dose and PEB conditions were adjusted to achieve only partial cross-linking of the photoresist film in order to improve adhesion during the subsequent bonding step.

The films were processed directly on the PET and exposed using an EVG 620 Precision Alignment System in contact mode employing a thin, 20-25 μm, PET coversheet between the film and the mask to avoid “sticking” of the film to the mask. When using a poorly adhesive substrate such as PET the uncured SU-8 film will preferentially stick to the glass mask after the contact exposure step. Alternatively, the mask or the resist film can be treated with a silicone or fluorinated release agent to prevent the mask sticking, thereby allowing the coversheet to be removed prior to exposure. In addition, exposures can be carried out in a proximity or projection mode, eliminating the need for a release layer since there is no contact between the mask and the film. The protective film, if used, was removed after exposure and the films were post exposure baked under a variety of reduced temperature and time conditions. The films were then developed using standard recommended conditions, rinsed thoroughly to remove any dissolved resist in the developer, then dried. The imaged films were then stored until bonded.

Choosing an appropriate temperature for PEB requires balancing improved adhesion with a loss in lithographic quality. Using lower temperatures and shorter times for PEB also requires shorter development times than “standard” processing due to possibility of overdevelopment. In this case, we artificially set the target as being able to get better than 2:1 aspect ratios, or 20 μm resist walls in 50 μm thick films. PEB temperatures of 60, 50, and 40° C. for 2 and 1 minutes were found to be appropriate for processing. Excellent results were obtained for both 25 and 50 μm films which were PEB at 60° C. for 2 minutes, followed by a 6 minute development with mild agitation.

### Example 1

Preliminary bonding tests were conducted on a DuPont Riston hot roll laminator using 20 μm thick cavity structures formed from spin coated SU-8 4000 coated on a PET substrate which had been PEB'd at 60° C. for 2 minutes. The patterned SU-8 structures were bonded to silicon wafers on a Riston hot roll laminator using a roll temperature of 90 to 100° C., a roll pressure of 45 psi, and roll speed of 0.3 m/min. In some cases, 3 passes were used for each wafer. Once the wafers were cooled to room temperature, the PET was peeled off leaving behind the patterned SU-8 cavity structures now bonded to the silicon wafer. All wafers were allowed to stand overnight under ambient conditions. The wafers were then screened for adhesion using a simple tape test. The tape test was performed with a piece of Scotch tape which was pressed down firmly onto the SU-8 structures and then pulled off vertical to the wafer. Retention of 100% of the structures was defined as “pass” and full removal was defined as “fail”: 5=Pass, 1=Fail. Tape tests were performed after several post bonding processes such as hard bake and a pressure cooker test. The wafers that passed the post bonding tape test were baked at 95° C. for 4 minutes, allowed to stand under ambient conditions overnight, and then again tested for adhesion. The results are shown in Table I.

TABLE I
Riston Laminator

| | Temp | Dev Delay | Pre-bake | Pressure | Speed | Passes | Respose | | |
|---|---|---|---|---|---|---|---|---|---|
| Trial No. | ° C. | days | yes-no | psi | m/min | # | T 95 | T 150 | T 250 |
| 1a | 60 | 0 | Y | 10 | 0.3 | 1 | 4 | 5 | 5 |
| 1b | 60 | 0 | N | 45 | 1.5 | 1 | 1 | 1 | 1 |
| 1c | 90 | 0 | Y | 45 | 1.5 | 5 | 5 | 5 | 5 |
| 1d | 90 | 0 | N | 10 | 0.3 | 5 | 4 | 5 | 5 |
| 1e | 60 | 7 | N | 10 | 1.5 | 5 | 4 | 5 | 5 |
| 1f | 60 | 7 | Y | 45 | 0.3 | 5 | 5 | 5 | 5 |
| 1g | 90 | 7 | N | 45 | 0.3 | 1 | 5 | 5 | 5 |
| 1h | 90 | 7 | Y | 10 | 1.5 | 1 | 5 | 5 | 5 |

### Example 2

Additional samples of 25 μm thick film containing the wall structure of various cavity sizes with wall widths varying from 10 μm to 100 μm were prepared from MicroForm 4025 micro-laminate films obtained from MicroChem. These films were processed as in Example 1 and then attached on the back side of the PET to 5 mil dicing tape to provide handling rigidity. These films were then bonded on an EVG® 820 Dry Film Lamination System at 85° C. under different pressure and speed conditions or on the DuPont Riston Laminator at 45 psi under different temperature and speed conditions. All films were well bonded to the silicon wafer upon removal of the PET carrier film bonded to the 5 mil dicing tape. All wafers also passed the tape test after the 250° C. hardbake although some did not pass after the 95 or 150° C. hardbakes: 5=Pass, 1=Fail. The results are shown in Table II.

TABLE II
EVG820 Laminator

| | Force | Chuck temp | Speed | Response | | | | | |
|---|---|---|---|---|---|---|---|---|---|
| Trial No. | N | ° C. | m/min | T 95 | T 150 | T 250 | PCT 95 | PCT 150 | PCT 250 |
| 2a | 1000 | 85 | 2 | 3 | 4 | 5 | — | — | 3 |
| 2b | 6500 | 85 | 2 | 3 | 5 | 5 | — | 5 | 1 |
| 2c | 6500 | 85 | 0.5 | 5 | 5 | 5 | 5 | 5 | 2 |
| 2d | 1000 | 85 | 0.5 | 1 | 3 | 4 | — | — | 1 |

### Example 3

Additional samples of 25 μm thick cavity structures on PET were prepared and processed as in Example 2. These films were then bonded on an EVG® 520 Wafer Bonding System at 10 mbar vacuum, 75° C. with the maximum temperature ramp and with various bonding pressures and pressure hold times prior to heating. All films were well bonded to the silicon wafer upon removal of the PET carrier film bonded to the 5 mil dicing tape. All wafers also passed the tape test after the 250° C. hardbake although some did not pass after the 95 or 150° C. hardbakes: 5=Pass, 1=Fail. The results are shown in Tables III and IV.

TABLE III
EVG520WB

| | Start temp | Vacuum | | Force | Press hold | Heat ramp | Bond temp | Heat time |
|---|---|---|---|---|---|---|---|---|
| Trial No. | ° C. | mbar | P ramp rat | mbar | min | sec | ° C. | min |
| 3a | 22 | 10 | max | 2000 | 0 | 45 | 75 | 0 |
| 3b | 22 | 10 | max | 1000 | =P set | 45 | 75 | 0 |
| 3c | 22 | 10 | max | 2000 | 5 | 45 | 75 | 0 |
| 3d | 22 | 10 | max | 2000 | 0 | 45 | 75 | 30 |
| 3e | 22 | 10 | max | 2000 | 5 | 45 | 95 | 30 |

TABLE IV

| | Response | | | | | |
|---|---|---|---|---|---|---|
| Trial No. | T 95 | T 150 | T 250 | PCT 95 | PCT 150 | PCT 250 |
| 3a | 4 | 5 | 5 | — | 5 | 3 |
| 3b | 3 | 3 | 5 | — | — | 3 |
| 3c | 4 | 5 | 5 | — | 5 | 1 |
| 3d | 1 | 4 | 5 | — | — | 1 |
| 3e | 5 | 5 | 5 | 5 | 5 | 3 |

### Example 4

Additional samples of 25 μm thick cavity structures on PET were prepared and processed as in Example 2. These films were then bonded on an SUSS MicroTec SB 6e Substrate Bonder at 95° C. with various temperature ramps, vacuum levels, bonding pressures and heat hold times using a statistical experimental design. All films were well bonded to the silicon wafer upon removal of the PET carrier film which was attached to the 5 mil dicing tape. All wafers also passed the tape test after both the 150° C. and 250° C. hardbake although a couple did not pass after the 95 hardbake: 5=Pass, 1=Fail. The results are shown in Tables V and VI.

TABLE V
SUSS SB 6e

| | Start temp | Vacuum | | Pressure | Press hold | Heat ramp | Bond temp | Heat time |
|---|---|---|---|---|---|---|---|---|
| Trial No. | ° C. | mbar | P ramp rate | mbar | sec | sec | ° C. | min |
| 4a | 25 | 10 | max | 750 | 0 | min | 95 | 0 |
| 4b | 25 | 10 | max | 750 | 0 | 180 | 95 | 5 |
| 4c | 25 | 10 | max | 3000 | 0 | min | 95 | 5 |
| 4d | 25 | 10 | max | 3000 | 0 | 180 | 95 | 0 |
| 4e | 25 | 10⁻² | max | 750 | 0 | min | 95 | 5 |
| 4f | 25 | 10⁻² | max | 750 | 0 | 180 | 95 | 0 |
| 4g | 25 | 10⁻² | max | 3000 | 0 | min | 95 | 0 |
| 4h | 25 | 10⁻² | max | 3000 | 0 | 180 | 95 | 5 |
| 4i | 25 | 10 | max | 3000 | 0 | min | 95 | 0 |

TABLE VI

| | Response | | | | | |
|---|---|---|---|---|---|---|
| Trial No. | T 95 | T 150 | T 250 | PCT 95 | PCT 150 | PCT 250 |
| 4a | 5 | 5 | 5 | 5 | 5 | 4 |
| 4b | 5 | 5 | 5 | 5 | 5 | 5 |
| 4c | 5 | 5 | 5 | 5 | 5 | 1 |
| 4d | 5 | 5 | 5 | 5 | 5 | 1 |
| 4e | 5 | 5 | 5 | 5 | 5 | 1 |
| 4f | 4 | 5 | 5 | — | 5 | 1 |
| 4g | 5 | 5 | 5 | 5 | 5 | 1 |
| 4h | 2 | 3 | 5 | — | — | 1 |
| 4i | 5 | 5 | 5 | 5 | 5 | 1 |

### Example 2-4 Pressure Cooker Test

All samples which passed the tape tests from Examples 2, 3 and 4 were placed in a pressure cooker at 125° C. and 15 psi for 100 hrs, cooled overnight, dried and retested with the tape test. All samples which passed the 95 and 150° C. hardbake tape tests also passed the pressure cooker test. None of the samples which were subsequently hardbaked at 250° C. completely passed the tape test. All of the larger structures of 0.5 and 1 mm failed on all tests. Some of the smaller structures with wall widths of 10 and 25 μm passed the test. The test results are included in the Tables above.

### Example 5

Samples of 20 μm thick film containing the wall structure of various cavity sizes with wall widths varying from 10 μm to 100 μm were prepared from MicroForm® 1000 DF20 micro-laminate films obtained from MicroChem. These films were processed as in Example 1. All films were well bonded to the silicon wafer upon removal of the PET carrier film. All wafers also passed the tape test after the 250° C. hardbake although some did not pass after the 95 or 150° C. hardbakes.

### Example 6

A sample of a 500 μm thick film containing wall structures of various cavity sizes with wall widths varying from 25 μm to 1 mm were prepared from experimental MicroForm® 4500N micro-laminate films obtained from MicroChem. This film was PEB'd at 60° C. for 2 minutes, then developed for several hours as recommended by the manufacturer, rinsed in isopropyl alcohol to remove residual developer then dried at room temperature overnight, The 500 μm tall wall structures were attached to a silicon wafer in an Optek DPL-24 Differential Pressure Laminator, without vacuum at 60° C., 10 psi for 20 sec. The PET carrier film was removed and the second side of the wall structure was attached to a ⅛ inch polycarbonate substrate at the same conditions then further attached at 90° C., 10 psi for 4 minutes. The combined structure was then heated at 120° C. for 60 minutes on a hot plate to firmly bond both substrates to the wall structures.

While the invention has been described above with reference to specific embodiments thereof, it is apparent that many changes, modifications, and variations can be made without departing from the inventive concept disclosed herein. Accordingly, it is intended to embrace all such changes, modifications and variations that fall within the spirit and broad scope of the appended claims. All patent applications, patents and other publications cited herein are incorporated by reference in their entirety.

What is claimed is:

1. A process for packaging a microelectrical, micromechanical, microelectromechanical (MEMS) or microfluidic component on a substrate, comprising the steps of:
(a) forming a first laminate comprising a first negative photoimagable polymeric photoresist layer positioned on a first substrate;
(b) forming a second laminate comprising a second negative photoimagable polymeric photoresist layer positioned on a second substrate;
(c) exposing the first laminate to radiation energy to form a latent imaged portion in the first photoimagable polymeric photoresist layer;
(d) bonding the first laminate to the second laminate so that the imaged portion is brought into contact with the second photoimagable polymeric photoresist layer;
(e) exposing a portion of the combined first and second photoimagable polymeric photoresist layers to radiation energy to form a second latent image in the combined photoresist layer; said combined exposed portions of the first and second photoresist layers corresponding to cover and wall portions, respectively, of at least one packaging structure for said microelectrical, micromechanical, microelectromechanical (MEMS) or microfluidic component;
(f) removing the second substrate from the bonded laminates;
(g) post exposure baking (PEB) the bonded laminates to crosslink the previously exposed areas of the films;
(h) developing the post exposure baked bonded laminates to remove the non-crosslinked portions of the first and second photoresist layers and leaving a resulting first side comprising the cross-linked portions corresponding to the packaging structure positioned on the first substrate;
(i) forming a second side comprising at least one microelectrical, micromechanical, microelectromechanical (MEMS) or microfluidic device on a third substrate;
(j) bonding the resulting first side of step (h) to the second side of step (i) so that each respective packaging structure overlaps each device and forms a bond with the third substrate; and
(k) removing the first substrate from the combined first and second sides.

2. The process of claim 1, wherein the first laminate at step (c) is post exposure baked and developed prior to bonding the second laminate in step (d).

3. The process of claim 1, wherein the combined first and second sides can be further laminated to a third or subsequent laminate (g) or (h), making a multilayer combined laminate.

4. The process of claim 1, wherein said first and second negative photoimagable polymeric photoresists comprises a negative acting photoimagable resist which can be undercrosslinked to a level that allows development of wall structures as small as 10 μm in width with aspect ratios greater than 1:1, but which is still tacky enough to maintain the capability to be subsequently bonded to a third substrate after exposure, PEB, development and drying.

5. The process of claim 1, wherein said first and second negative photoimagable polymeric comprise
(A) one or more bisphenol A-novolac epoxy resins according to Formula I 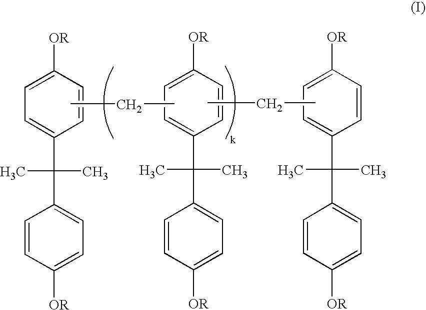
wherein each group R in Formula I is individually selected from glycidyl or hydrogen and k in Formula I is a real number ranging from 0 to about 30;
(B) one or more epoxy resins selected from the group represented by Formulas BIIa and BIIb above, wherein each R₁ R₂ and R₃ in Formula BIIa are independently selected from the group consisting of hydrogen or alkyl groups having 1 to 4 carbon atoms and the value of p in Formula BIIa is a real number ranging from 1 to 30; the values of n and m in Formula BIIb are independently real numbers ranging from 1 to 30 and each R₄ and R₅ in Formula BIIb are independently selected from hydrogen, alkyl groups having 1 to 4 carbon atoms, or trifluoromethyl;
(C) one or more cationic photoinitiators or photoacid generators; and
(D) little or no solvent.

6. The process of claim 5, wherein said first and second negative photoimagable polymeric photoresists further comprise additional ingredients selected from the group consisting of one or more epoxy resins (E), one or more reactive monomers (F), one or more photosensitizer compounds (G), one or more adhesion promoters (H), an organic aluminum compound (K), and combinations thereof.

7. The process of claim 1, wherein said first and second negative photoimagable polymeric photoresists comprise
(A) one or more bisphenol A-novolac epoxy resins according to Formula I 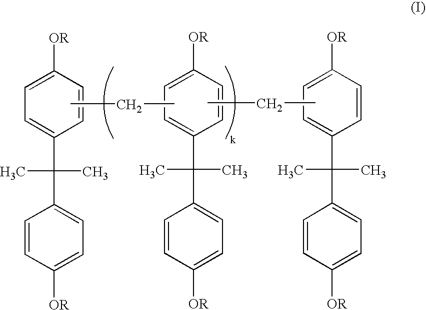
wherein each group R in Formula I is individually selected from glycidyl or hydrogen and k in Formula I is a real number ranging from 0 to about 30;
(B) at least one polycaprolactone polyol reactive diluent with the structure shown as Formula 2, 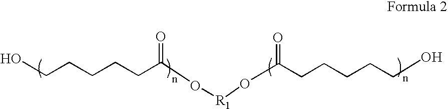
where R₁ is a proprietary aliphatic hydrocarbon group, and with average n=2 or with the structure shown as Formula 3, 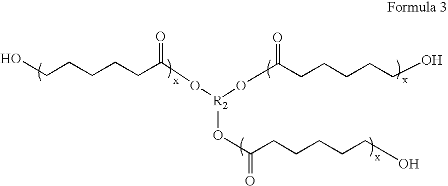
where R₂ is a proprietary aliphatic hydrocarbon group and with average x=1.
(C) one or more cationic photoinitiators (also known as photoacid generators or PAGs); and
(D) little or no solvent.

8. The process of claim 7, wherein said first and second negative photoimagable polymeric photoresists further comprise one or more additional ingredients selected from the group consisting of a reactive monomer component (D), a photosensitizer component (E), a dye component (F), and a dissolution rate control agent (G).

9. The process of claim 1, wherein said process produces cavities, caps, walls or channels that cover or encircle active areas of a device structure.

10. A process for packaging a microelectrical, micromechanical, microelectromechanical (MEMS) or microfluidic component on a substrate, comprising the steps of:
(a) forming a laminate comprising a negative photoimagable polymeric photoresist layer positioned on a substrate;
(b) exposing a portion of the photoimagable polymeric photoresist layer to radiation energy to form a latent image in the photoresist layer; said exposed portions of the photoresist layers corresponding to wall portions of at least one packaging structure for said microelectrical, micromechanical, microelectromechanical (MEMS) or microfluidic component;
(c) removing the substrate from the bonded laminates;
(d) post exposure baking (PEB) the bonded laminates to crosslink the previously exposed areas of the films;
(e) developing the post exposure baked bonded laminates to remove the non-crosslinked portions of the first and second photoresist layers and leaving a resulting first side comprising the cross-linked portions corresponding to the packaging structure positioned on the first substrate;
(f) forming a second side comprising at least one microelectrical, micromechanical, microelectromechanical (MEMS) or microfluidic device on a third substrate;
(g) bonding the resulting first side of step (e) to the second side of step (f) so that each respective packaging structure overlaps each device and forms a bond with the third substrate; and
(h) removing the first substrate from the combined first and second sides.

11. The process of claim 10, wherein said negative photoimagable polymeric photoresist comprises a negative acting photoimagable resist which can be undercrosslinked to a level that allows development of wall structures as small as 10 μm in width with aspect ratios greater than 1:1, but which is still tacky enough to maintain the capability to be subsequently bonded to a third substrate after exposure, PEB, development and drying.

12. The process of claim 10, wherein said negative photoimagable polymeric photoresist comprises
(A) one or more bisphenol A-novolac epoxy resins according to Formula I 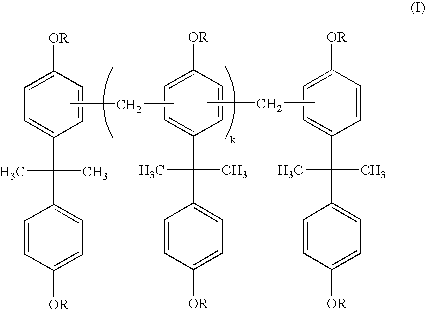
wherein each group R in Formula I is individually selected from glycidyl or hydrogen and k in Formula I is a real number ranging from 0 to about 30;
(B) one or more epoxy resins selected from the group represented by Formulas BIIa and BIIb above, wherein each R₁ R₂ and R₃ in Formula BIIa are independently selected from the group consisting of hydrogen or alkyl groups having 1 to 4 carbon atoms and the value of p in Formula BIIa is a real number ranging from 1 to 30; the values of n and m in Formula BIIb are independently real numbers ranging from 1 to 30 and each R₄ and R₅ in Formula BIIb are independently selected from hydrogen, alkyl groups having 1 to 4 carbon atoms, or trifluoromethyl;
(C) one or more cationic photoinitiators or photoacid generators; and
(D) little or no solvent.

13. The process of claim 12, wherein said negative photoimagable polymeric photoresists further comprises additional ingredients selected from the group consisting of one or more epoxy resins (E), one or more reactive monomers (F), one or more photosensitizer compounds (G), one or more adhesion promoters (H), an organic aluminum compound (K), and combinations thereof.

14. The process of claim 1, wherein said negative photoimagable polymeric photoresist comprises
(A) one or more bisphenol A-novolac epoxy resins according to Formula I 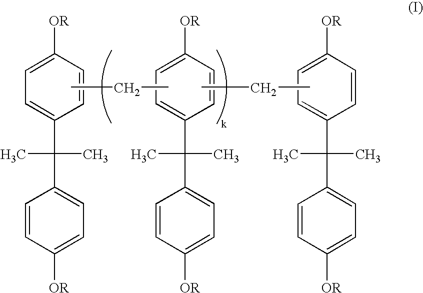
wherein each group R in Formula I is individually selected from glycidyl or hydrogen and k in Formula I is a real number ranging from 0 to about 30;
(B) at least one polycaprolactone polyol reactive diluent with the structure shown as Formula 2, 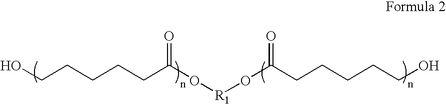
where R₁ is a proprietary aliphatic hydrocarbon group, and with average n=2 or with the structure shown as Formula 3, 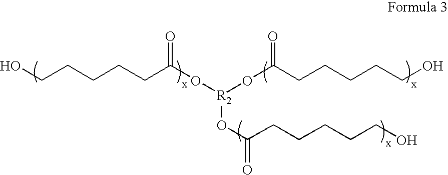
where R₂ is a proprietary aliphatic hydrocarbon group and with average x=1.
(C) one or more cationic photoinitiators (also known as photoacid generators or PAGs); and
(D) little or no solvent.

15. The process of claim 14, wherein said negative photoimagable polymeric photoresist further comprises one or more additional ingredients selected from the group consisting of a reactive monomer component (D), a photosensitizer component (E), a dye component (F), and a dissolution rate control agent (G).

16. The process of claim 10, wherein said process produces a wall layer.

17. The process of claim 10, further comprising the step of bonding said second layer on said third substrate to a fourth substrate.
